(19) United States
(12) Patent Application Publication
(10) Pub. No.: US 2026/0260028 A1
(43) Pub. Date: Sep. 3, 2026

(54) COUNTER DISTORTION METHOD FOR A THIN WALL STRUCTURE

(71) Applicant: RTX Corporation, Farmington, CT (US)

(72) Inventors: Lawrence Binek, Glastonbury, CT (US); Dean Sirois, Enfield, CT (US)

(21) Appl. No.: 19/067,094

(22) Filed: Feb. 28, 2025

(51) Int. Cl. G06F 30/13

(52) U.S. Cl. CPC G06F 30/13

(57) ABSTRACT

A thin walled structure includes a primary structure wall connected to a shielding wall with a plurality of support pins that extend from the shielding wall to the primary structure wall. A method for printing a thin walled structure includes the steps of: modeling, using distortion analysis software, a method of making a primary structure wall to generate a distortion analysis; inputting the distortion analysis into a digital model of the primary structure wall to determine a desirable layout and thickness for a support wall and a plurality of support pins that will connect with the primary support structure wall to form a thin walled structure; integrating the desirable layout and thickness for a support wall and a plurality of support pins into a build model of the primary structure wall to create a supported build model; and printing, using the supported build model, the thin walled structure.

The present disclosure relates generally to parts made with a laser beam powder bed fusion (PBF-L) technique and, more particularly, thin wall parts made with PBF-L techniques.

Building thin-walled features in using PBF-L techniques can be challenging due to the propensity for distortion to occur. Distortion compensation tools can assist in limiting distortion effects but often require significant calibration to result in a desired degree of correction.

### SUMMARY

One aspect of this disclosure is directed to a thin walled structure including a primary structure wall connected to a shielding wall with a plurality of support pins that extend from the shielding wall to the primary structure wall.

Another aspect of this disclosure is directed to a method of making a thin walled structure that includes the step of manufacturing, using PBF-L or PBF-EB techniques, a primary structure wall connected to a shielding wall with a plurality of support pins that extend from the shielding wall to the primary structure wall.

Another aspect of this disclosure is directed to a method for printing a thin walled structure with PBF-L or PBF-EB techniques include the steps of: modeling, using distortion analysis software, a method of making a primary structure wall with PBF-L or PBF-EB techniques to generate a distortion analysis; inputting the distortion analysis into a digital model of the primary structure wall to determine a desirable layout and thickness for a support wall and a plurality of support pins that will connect with the primary support structure wall to form a thin walled structure when printed; integrating the desirable layout and thickness for a support wall and a plurality of support pins into a build model of the primary structure wall to create a supported build model of the thin walled structure that includes the primary wall structure, the support wall and the plurality of support pins; and printing, using the supported build model and PBF-L or PBF-EB techniques, the thin walled structure.

### BRIEF DESCRIPTION OF THE DRAWINGS

FIG. 1 is a perspective view of a primary structure wall having a degree of distortion that exceeds allowable tolerances.

FIG. 2 is close up view of a primary structure wall offset from a shielding wall with a plurality of support pins.

FIG. 3 is perspective view of a primary structure wall offset from a shielding wall with a plurality of support pins.

FIG. 4 is perspective view of a primary structure wall after removal of a shielding wall and plurality of support pins.

FIG. 5 is a flowchart for integrating the method of the present disclosure into a model for printing a primary structure wall.

### DETAILED DESCRIPTION

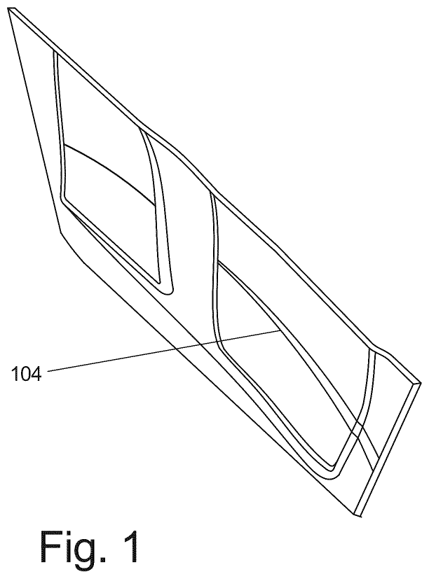

Gas turbine engines include a number of components having primary structure walls, particularly those that include sheet metal-type features. Such parts, which include various ducts, plenums, etc., are difficult to make using laser beam powder bed fusion (PBF-L) techniques due to the propensity for distortion to occur with thin (e.g. less than 0.25 inch (6.4 mm)) walls that may impact part stiffness. Significant distortion can occur because of internal stresses generated by relatively large areas of thermal mass. Alternately, a thin wall can be characterized as a wall having a planar dimension to width ratio (i.e., an aspect ratio) of eight to one (8:1) or greater (i.e., one (1) or both of the planar dimensions being eight (8) times or more than the thickness of the part). FIG. 1 shows an unsupported primary structure wall 104 made with PBG-L techniques that exhibits a degree of distortion that exceeds allowable tolerances for planar distortion. While distortion compensation tools can assist in limiting distortion effects, such tools often require significant calibration to result in a desired degree of correction. The counter distortion method for thin primary structure walls made with PBF-L techniques disclosed in this application aims to provide in-process rigidity to a parent structure to limit or eliminate distortion effects that will permit the manufacture of such structures within allowable tolerances for planar distortion. In some examples, it is desirable for primary structure walls 104 to have distortions of no more than ±0.005 inch (±0.127 mm) to ±0.020 inch (±0.51 mm) across any planar surface of the primary structure walls 104.

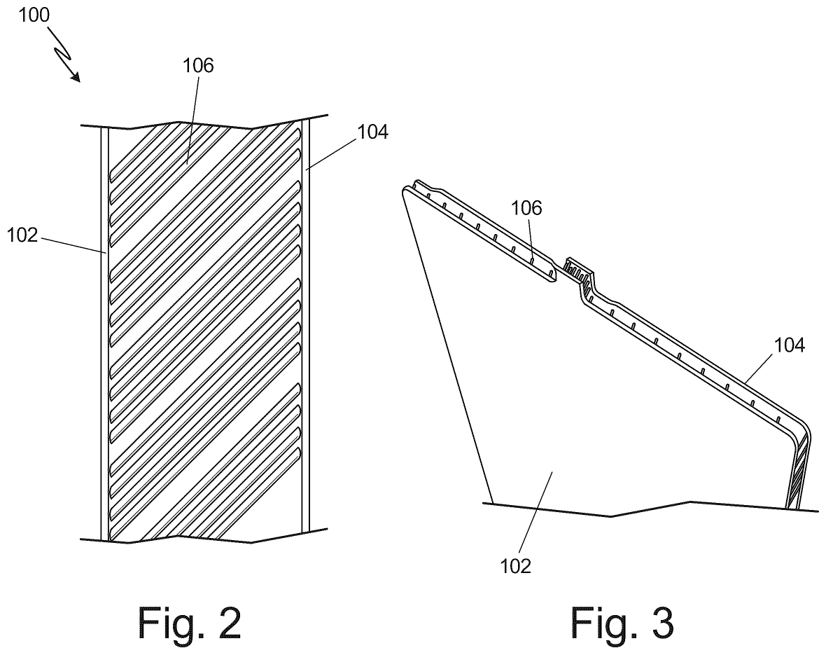

FIG. 2 shows a structure 100 that includes a shielding wall 102 off-set from a primary structure wall 104. A plurality of support pins 106 connect the shielding wall 102 to the primary structure wall 104. The shielding wall 102 and the primary structure all 104 can have similar thickness, e.g., less than 0.25 inch (6.4 mm), or any other thinness, including different thicknesses, deemed appropriate for a particular application. The plurality of support pins 106 are sized and positioned to allow the shielding wall 102 and the plurality of support pins 106 to cooperate to permit the primary structure wall 104 to be manufactured within allowable tolerances for planar distortion. In one example, the plurality of support pins 106 can be about 0.01 inches (0.25 mm) to 0.10 inches (2.5 mm) in diameter and extend from the shielding wall 102 about 0.025 inches (0.6 mm) to about 0.05 inches (1.27 mm) to connect with the primary structure wall 104 at a forty-five degree (45°) inclination or other suitable angle. techniques or, for some applications electron beam powder bed fusion (PBF-EB) techniques, vat photopolymerization, or polymer PBF In other examples, the support pins 106 can have different dimensions and connect with the primary structure wall 104 at different angles. The plurality of support pins 106 can be distributed as a function of anticipated distortion with either an increase in support pin 106 density or support pin 106 thickness or both in regions of the primary structure wall 104 where excessive distortion is expected in the absence of the combination of the shielding wall 102 and the plurality of support pins 106. The shielding wall 102 and the plurality of support pins 106 can be built with a material density sufficient to permit the primary structure wall 104 to be manufactured within allowable tolerances for planar distortion while allowing for ready removal after completion of the thin walled structure 100 build. FIG. 3 presents another view of the thin walled structure 100 that includes a shielding wall 102 off-set from a primary structure wall 104 with a plurality of support pins 106.

The thin walled structure 100, including the shielding wall 102, primary structure wall 104 and support pins 106 can be made from any material suitable for a desired application. For example, the thin walled structure 100 can be made from aluminum, an aluminum alloy, titanium, a titanium alloy, nickel-based superalloys, steels, polymeric materials, or any other material deemed appropriate for a particular application. While the shielding wall 102, primary structure wall 104, and support pins 106 can all be made from the same material to simplify manufacturing, if appropriate for a particular application, they can also be made from different materials. As discussed above, the thin walled structure 100, including the shielding wall 102, primary structure wall 104, and support pins 106 can be made using PBF-L techniques or, for some applications, electron beam powder bed fusion (PBF-EB) techniques, vat photopolymerization, or polymer PBF.

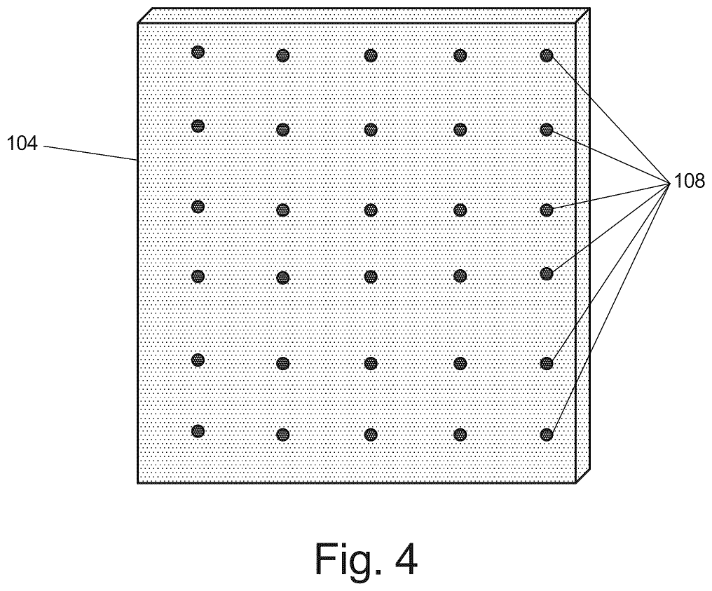

Once the thin walled structure 100 build has been completed and any desired thermal post processing has been completed, the shielding wall 102 and the plurality of support pins 106 can be removed from the primary structure wall 104 by detaching the plurality of support pins 106 from the primary structure wall 104 using hand tools or any other convenient tools. The shielding wall 102 and the plurality of support pins 106 will then separate from the primary structure wall 104, leaving the desired primary structure wall 104 to be used in a desired application. As shown in FIG. 4, separation of the plurality of support pins 106 from the primary structure wall 104 will leave a plurality of minor, detectable artifacts 108 on the primary structure wall 104 that will not interfere with the operational use of the primary structure wall 104. The plurality of detectable artifacts 108 on the primary structure wall 104 can include short, raised artifacts 108 that do not interfere with operational use of the primary structure wall 104, localized disruptions to the primary structure wall 104 microstructure that do not impact mechanical properties of the primary structure wall 104, or any other artifacts that do not interfere with the operational use of the primary structure wall 104.

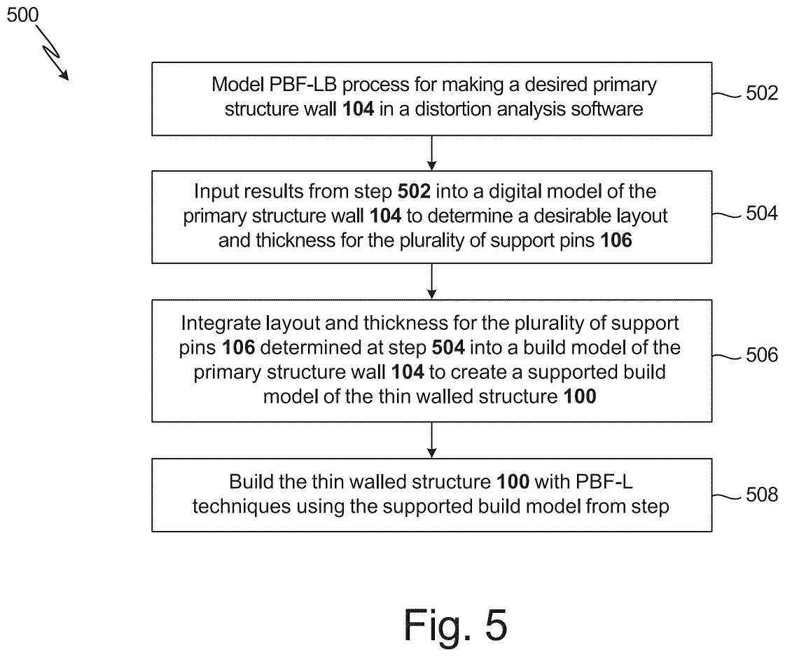

FIG. 5 is flowchart of a method 500 for integrating the disclosed process into a model for manufacturing a primary structure wall 104 using PBF-L techniques. At step 502, the PBF-L process for making a desired primary structure wall 104 is modeled in a distortion analysis software. The distortion analysis software can be any such software that is deemed to be suitable for modeling distortion that can occur when printing the desired primary structure wall 104 using PBF-L techniques. At step 504, the results from step 502 are input into a digital model of the primary structure wall 104, which determines a desirable layout and thickness for the plurality of support pins 106. Support pin 106 layout and thickness are determined by experimental and modeled data included in the digital model. At step 506, the desirable layout and thickness for the plurality of support pins 106 determined by the model of step 504 is integrated into a build model of the primary structure wall 104 to create a supported build model of the thin walled structure 100 to include the primary wall structure 104, support wall 102, and the plurality of support pins 106. The supported build model from step 506 can then be used to build the thin walled structure 100 using PBF-L techniques at step 508.

The method is scalable to any size primary wall structure 104 that can benefit from the inclusion of a support wall 102 and support pins 106 to address undesirable distortion during manufacture using PBF-L or other additive manufacturing techniques. Exemplary primary wall structures 104 include various ducts (e.g., inlet and exhaust ducts), plenums, shrouds, combustor walls, casings, manifolds, certain vane/blade features (e.g., baffles), struts, etc. A person of ordinary skill will recognize that the disclosed method can be used to build other primary wall structures 104 as well. The disclosed method allows primary wall structures 104 to be built within allowable tolerances for planar distortion without incurring significant cost.

### Discussion of Possible Embodiments

The following are non-exclusive descriptions of possible embodiments of the present invention.

A thin walled structure includes a primary structure wall connected to a shielding wall with a plurality of support pins that extend from the shielding wall to the primary structure wall.

The thin walled structure of the preceding paragraph can optionally include, additionally and/or alternatively, any one or more of the following features, configurations and/or additional elements:

The plurality of support pins connect with the primary structure wall at a forty-five degree (45°) inclination.

The shielding wall and the primary structure both have a thickness less than 0.25 inch (6.4 mm).

The plurality of support pins are sized and positioned to allow the shielding wall and the plurality of support pins to cooperate to permit the primary structure wall to be manufactured within allowable tolerances for planar distortion.

The plurality of support pins are about 0.01 inches (0.25 mm) to 0.10 inches (2.5 mm) in diameter and extend from the shielding wall about 0.025 inches (0.6 mm) to about 0.05 inches (1.27 mm) to connect the shielding wall with the primary structure wall.

The shielding wall, plurality of support pins, and primary structure wall are made from aluminum, an aluminum alloy, titanium, a titanium alloy, nickel-based superalloys, steels, or a polymeric material.

The shielding wall, plurality of support pins, and primary structure wall are made with laser powder bed fusion (PBF-L) techniques or electron beam powder bed fusion (PBF-EB) techniques.

The primary structure wall is configured to be detached from the shielding wall and plurality of support pins such that separation of the plurality of support pins from the primary structure wall leaves a plurality of detectable artifacts on the primary structure wall, wherein the plurality of detectable artifacts do not interfere with operational use of the primary structure wall.

The plurality of detectable artifacts are one or more of artifacts that do not interfere with operational use of the primary structure wall or localized disruptions to the microstructure of the primary structure wall.

A method of making a thin walled structure that includes the step of printing, using PBF-L or PBF-EB techniques, a primary structure wall connected to a shielding wall with a plurality of support pins that extend from the shielding wall to the primary structure wall.

The method of the preceding paragraph can optionally include, additionally and/or alternatively, any one or more of the following features, configurations and/or additional elements:

The plurality of support pins connect with the primary structure wall at a 45° inclination.

The shielding wall and the primary structure both have a thickness less than 0.25 inch (6.4 mm).

The plurality of support pins are sized and positioned to allow the shielding wall and the plurality of support pins to cooperate to permit the primary structure wall to be manufactured within allowable tolerances for planar distortion.

The plurality of support pins are about 0.01 inches (0.25 mm) to 0.10 inches (2.5 mm) in diameter and extend from the shielding wall about 0.025 inches (0.6 mm) to about 0.05 inches (1.27 mm) to connect the shielding wall with the primary structure wall.

The shielding wall, plurality of support pins, and primary structure wall are made from aluminum, an aluminum alloy, titanium, a titanium alloy, nickel-based superalloys, steels, or a polymeric material.

The method further includes detaching the primary structure wall from the shielding wall and plurality of support pins such that separation of the plurality of support pins from the primary structure wall leaves a plurality of detectable artifacts on the primary structure wall, wherein the plurality of detectable artifacts do not interfere with operational use of the primary structure wall.

The plurality of detectable artifacts are one or more of artifacts that do not interfere with operational use of the primary structure wall or localized disruptions to the microstructure of the primary structure wall.

A method for printing a thin walled structure with PBF-L or PBF-EB techniques include the steps of: modeling, using distortion analysis software, a method of making a primary structure wall with PBF-L or PBF-EB techniques to generate a distortion analysis; inputting the distortion analysis into a digital model of the primary structure wall to determine a desirable layout and thickness for a support wall and a plurality of support pins that will connect with the primary support structure wall to form a thin walled structure when printed; integrating the desirable layout and thickness for a support wall and a plurality of support pins into a build model of the primary structure wall to create a supported build model of the thin walled structure that includes the primary wall structure the support wall and the plurality of support pins; and printing, using the supported build model and PBF-L or PBF-EB techniques, the thin walled structure.

The method of the preceding paragraph can optionally include, additionally and/or alternatively, any one or more of the following features, configurations and/or additional elements:

The primary structure wall is configured to be detached from the shielding wall and plurality of support pins such that separation of the plurality of support pins from the primary structure wall leaves a plurality of detectable artifacts on the primary structure wall, wherein the plurality of detectable artifacts do not interfere with operational use of the primary structure wall.

The plurality of detectable artifacts are one or more of artifacts that do not interfere with operational use of the primary structure wall or localized disruptions to the microstructure of the primary structure wall.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A thin walled structure comprising:
a primary structure wall connected to a shielding wall with a plurality of support pins that extend from the shielding wall to the primary structure wall.

2. The thin walled structure of claim 1, wherein the plurality of support pins connect with the primary structure wall at a 45° inclination.

3. The thin walled structure of claim 1, wherein the shielding wall and the primary structure both have a thickness less than 0.25 inch (6.4 mm).

4. The thin walled structure of claim 1, wherein the plurality of support pins are sized and positioned to allow the shielding wall and the plurality of support pins to cooperate to permit the primary structure wall to be manufactured within allowable tolerances for planar distortion.

5. The thin walled structure of claim 4, wherein the plurality of support pins are about 0.01 inches (0.25 mm) to 0.10 inches (2.5 mm) in diameter and extend from the shielding wall about 0.025 inches (0.6 mm) to about 0.05 inches (1.27 mm) to connect the shielding wall with the primary structure wall.

6. The thin walled structure of claim 1, wherein the shielding wall, plurality of support pins, and primary structure wall are made from aluminum, an aluminum alloy, titanium, a titanium alloy, nickel-based superalloys, steels, or a polymeric material.

7. The thin walled structure of claim 1, wherein the shielding wall, plurality of support pins, and primary structure wall are made with laser powder bed fusion (PBF-L) techniques or electron beam powder bed fusion (PBF-EB) techniques.

8. The thin walled structure of claim 1, wherein the primary structure wall is configured to be detached from the shielding wall and plurality of support pins such that separation of the plurality of support pins from the primary structure wall leaves a plurality of detectable artifacts on the primary structure wall, wherein the plurality of detectable artifacts do not interfere with operational use of the primary structure wall.

9. The thin walled structure of claim 8, wherein the plurality of detectable artifacts are one or more of artifacts that do not interfere with operational use of the primary structure wall or localized disruptions to the microstructure of the primary structure wall.

10. A method of making a thin walled structure, comprising the steps of:
printing, using PBF-L or PBF-EB techniques, a primary structure wall connected to a shielding wall with a plurality of support pins that extend from the shielding wall to the primary structure wall.

11. The method of claim 10, wherein the plurality of support pins connect with the primary structure wall at a 45° inclination.

12. The method of claim 10, wherein the shielding wall and the primary structure both have a thickness less than 0.25 inch (6.4 mm).

13. The method of claim 1, wherein the plurality of support pins are sized and positioned to allow the shielding wall and the plurality of support pins to cooperate to permit the primary structure wall to be manufactured within allowable tolerances for planar distortion.

14. The method of claim 13, wherein the plurality of support pins are about 0.01 inches (0.25 mm) to 0.10 inches (2.5 mm) in diameter and extend from the shielding wall about 0.025 inches (0.6 mm) to about 0.05 inches (1.27 mm) to connect the shielding wall with the primary structure wall.

15. The method of claim 10, wherein the shielding wall, plurality of support pins, and primary structure wall are made from aluminum, an aluminum alloy, titanium, a titanium alloy, nickel-based superalloys, steels, or a polymeric material.

16. The method of claim 10, further comprising:
detaching the primary structure wall from the shielding wall and plurality of support pins such that separation of the plurality of support pins from the primary structure wall leaves a plurality of detectable artifacts on the primary structure wall, wherein the plurality of detectable artifacts do not interfere with operational use of the primary structure wall.

17. The method of claim 16, wherein the plurality of detectable artifacts are one or more of artifacts that do not interfere with operational use of the primary structure wall or localized disruptions to the microstructure of the primary structure wall.

18. A method for printing a thin walled structure with PBF-L or PBF-EB techniques, comprising the steps of:
modeling, using distortion analysis software, a method of making a primary structure wall with PBF-L or PBF-EB techniques to generate a distortion analysis;
inputting the distortion analysis into a digital model of the primary structure wall to determine a desirable layout and thickness for a support wall and a plurality of support pins that will connect with the primary support structure wall to form a thin walled structure when printed;
integrating the desirable layout and thickness for a support wall and a plurality of support pins into a build model of the primary structure wall to create a supported build model of the thin walled structure that includes the primary wall structure the support wall and the plurality of support pins; and
printing, using the supported build model and PBF-L or PBF-EB techniques, the thin walled structure.

19. The method of claim 18, wherein the primary structure wall is configured to be detached from the shielding wall and plurality of support pins such that separation of the plurality of support pins from the primary structure wall leaves a plurality of detectable artifacts on the primary structure wall, wherein the plurality of detectable artifacts do not interfere with operational use of the primary structure wall.

20. The method of claim 19, wherein the plurality of detectable artifacts are one or more of artifacts that do not interfere with operational use of the primary structure wall or localized disruptions to the microstructure of the primary structure wall.
